(19) United States
(12) Patent Application Publication
(10) Pub. No.: US 2012/0205782 A1
(43) Pub. Date: Aug. 16, 2012

(54) Imprint Apparatus, Imprint Method, and Process Condition Selection Method

(76) Inventor: Masafumi ASANO, Kanagawa (JP)

(21) Appl. No.: 13/238,117

(22) Filed: Sep. 21, 2011

(30) Foreign Application Priority Data
Feb. 16, 2011 (JP) 2011-030952

(51) Int. Cl. H01L 29/02; G03B 27/42

(52) U.S. Cl. 257/618; 355/53; 257/E29.002

(57) ABSTRACT

An imprint apparatus of one embodiment includes: a resist dropping unit adapted to drop resist onto a substrate; a patterning unit adapted to pattern the resist into transfer patterns corresponding to the template patterns; and a control unit configured to change a dropping condition for a resist dropping process shot by shot. The control unit is adapted to control, as the dropping condition, the distance to the position of a droplet of the resist to be dropped onto the substrate from a position on the substrate to be pressed with an assessment pattern, the assessment pattern being one of the template patterns that is to be assessed.

### CROSS-REFERENCE TO RELATED APPLICATIONS

This application is based upon and claims the benefit of priority from the prior Japanese Patent Application No. 2011-030952, filed on Feb. 16, 2011; the entire contents of which are incorporated herein by reference.

### FIELD

Embodiments described herein relate generally to an imprint apparatus, an imprint method, and a process condition selection method.

### BACKGROUND

Nano Imprint Lithography (NIL) has been used as one of the techniques for use in a lithography process in the production of semiconductor devices.

NIL is a technique in which, by pressing a template against a wafer which is a substrate to be processed, patterns corresponding to the template patterns are transferred onto the wafer, the template having been formed by, for example, electron beam (Electron Beam: EB) drawing.

When NIL is performed, the template is brought close to the wafer with a photo-curing agent already dropped onto the wafer, whereby the template is brought into contact with the photo-curing agent. Then, the photo-curing agent is filled within the template patterns by capillary phenomenon, and the photo-curing agent is irradiated with UV light in this state. The photo-curing agent is hardened, and then mold release of the template from the wafer is performed.

In performing such NIL, defects of two types tend to occur, which are: an unfilled defect which occurs because the photo-curing agent does not flow throughout the template; and a mold release defect which occurs with a pattern (a hardened photo-curing agent) is peeled off from the substrate at the time of mold release.

In the NIL, however, assessment (process assessment) of an exposure amount as in the case of the light lithography and a dimensional change to defocus has not been established yet. Therefore, it is desired that the process assessment in the NIL be performed efficiently.

### BRIEF DESCRIPTION OF THE DRAWINGS

FIG. 1 is a diagram of the configuration of the imprint apparatus according to a first embodiment;

FIGS. 2A to 2D are explanatory diagrams for a procedure by which imprint steps are performed;

FIGS. 3A and 3B are explanatory diagrams for unfilled defects;

FIG. 4 is an explanatory diagram for a position onto which resist is dropped;

FIGS. 5A and 5B are exemplary diagrams of an assessment result with respect to unfilled defects in a case where a filling time condition and a drop position condition are changed shot by shot;

FIGS. 6A and 6B are exemplary diagrams of the assessment result with respect to unfilled defects in a case where a drop amount condition and a drop position condition are changed shot by shot;

FIGS. 7A and 7B are exemplary diagrams of the assessment result of unfilled defects in a case where a drop amount condition and a filling time condition are changed shot by shot;

FIGS. 8A and 8B are explanatory diagrams for mold release defects;

FIG. 9 is an explanatory diagram for a mold release speed and a mold release angle; and

FIGS. 10A and 10B are exemplary diagrams of an assessment result with respect to mold release defects in a case where a mold release speed and a mold release angle are changed shot by shot.

### DETAILED DESCRIPTION

In general, according to one embodiment, an imprint apparatus is provided. The imprint apparatus includes a resist dropping unit, a patterning unit, and a control unit. The resist dropping unit is adapted to drop resist serving as a transfer material onto a substrate onto which template patterns formed in a template are to be transferred. The patterning unit is adapted to press the template against the resist on the substrate for a predetermined length of time to fill the resist into the template patterns, to harden the resist after the filling, and then to perform mold release in which the template is separated from the hardened resist, such that the resist is patterned into transfer patterns corresponding to the template patterns. The control unit is adapted to control a condition of dropping in a resist dropping process, which is performed by the resist dropping unit, in such a manner that the condition of dropping is changed shot by shot for a plurality of shots set on the substrate. Further, the control unit is adapted to control, as the condition of dropping, the distance to the position of a droplet of the resist to be dropped onto the substrate from a position in the substrate to be pressed with an assessment pattern, the assessment pattern being one of the template patterns that is to be assessed.

Exemplary embodiments of the imprint apparatus, an imprint method, and a process condition selection method will be explained below in detail with reference to the accompanying drawings. The present invention is not limited to the following embodiments.

### First Embodiment

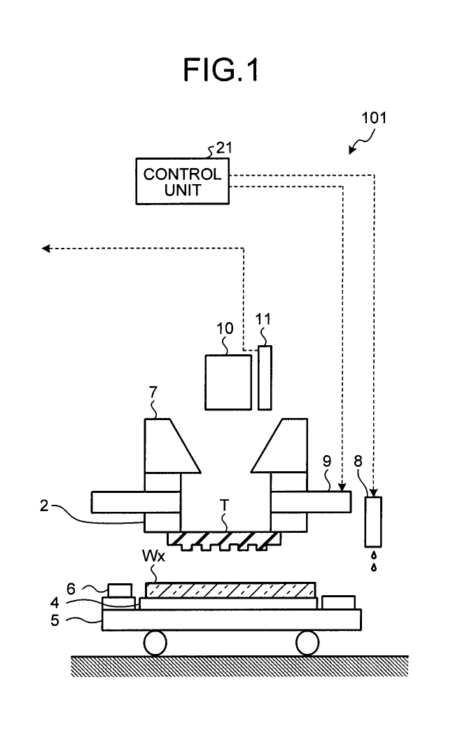

FIG. 1 is a diagram of the configuration of the imprint apparatus according to a first embodiment. The imprint apparatus 101 is an apparatus for transferring, onto to a transfer-receiving substrate (substrate to be processed) such as a wafer Wx, template patterns (such as circuit patterns) of a template (original form) T which is a mold substrate. The imprint apparatus 101 of this embodiment is adapted to transfer the template patterns onto the wafer Wx under process conditions various from shot to shot so that unfilled defects, which occur as a result of failure of the resist to flow into the template pattern, can be assessed. In this embodiment, assessments are made with respect to kinds of resist that enable prevention of unfilled defects, and process margins at the time of imprint that allow prevention of mold release defects.

The imprint apparatus 101 includes an original form stage 2, a substrate chuck 4, a sample stage 5, a reference mark 6, an alignment sensor 7, a liquid dropping device 8, a stage base 9, a UV light source 10, and an optical microscope 11. Additionally, the imprint apparatus 101 of this embodiment includes a control unit 21.

While the wafer Wx is placed on the sample stage 5, the sample stage 5 moves within a plane (within a horizontal plane) that is parallel to the wafer Wx placed. The sample stage 5 causes the wafer Wx to move to a location below the liquid dropping device 8 when the resist serving as a transfer material is dropped on the wafer Wx, and to move to the wafer Wx to a location under the template T when an imprint process on the wafer Wx is performed.

Additionally, the substrate chuck 4 is provided on the sample stage 5. The substrate chuck 4 is adapted to fix the wafer Wx at a predetermined position on the sample stage 5. Additionally, a reference mark 6 is provided on the sample stage 5. The reference mark 6 is a mark used for detecting the position of the sample stage 5, and is used for alignment in loading the wafer Wx on the sample stage 5.

The original form stage 2 is provided to the bottom side (the wafer Wx side) of the stage base 9. The original form stage 2 is adapted to fix the template T to a predetermined position thereof by vacuum adsorption, via the back side of the template T (the surface of one side thereof on which the template patterns are not formed).

The stage base 9 supports the template T by the original form stage 2, and is adapted to press the template patterns of the template T against the resist on the wafer Wx. By moving in the upward and downward direction (vertical direction), the stage base 9 presses the template T against the resist, and separates the template T from the resist (performs mold release). The resist for use in imprint is, for example, resin (a photo-curing agent)(a medicinal solution) having, e.g., a photo-curing property. Additionally, the alignment sensor 7 is provided on the stage base 9. The alignment sensor 7 is a sensor for detecting the position of the wafer Wx and detecting the position of the template T.

The liquid dropping device 8 is a device for dropping the resist on the wafer Wx by the inkjet method. An ink-jet head (not illustrated) included in the liquid dropping device 8 has plural minute orifices for jetting droplets of the resist. In accordance with the pattern density of the template patterns formed on the template T, the liquid dropping device 8 controls positions onto which droplets fall.

The UV light source 10 is a light source for radiating UV light, and is provided in a location above the stage base 9. The UV light source 10 is adapted to radiate UV light from a place above the template T while the template T is pressed against the resist.

The optical microscope 11 is a microscope by which to observe, through the template T which is substantially transparent, the resist (the resist after mold release) onto which the template patterns have been transferred. The optical microscope 11 is provided in a location above the stage base 9.

Note that the optical microscope 11 may be placed outside the imprint apparatus 101. In this case, the resist on the wafer Wx is observed by the optical microscope 11 after the imprinted wafer Wx has been taken out to the outside of the imprint apparatus 101.

The control unit 21 is connected to the components of the imprint apparatus 101, and is adapted to control the components. FIG. 1 illustrates the control unit 21 as being connected to the liquid dropping device 8 and the stage base 9, and the connection thereof with the other components is not illustrated. When imprint for assessment with respect to unfilled defects is executed, the control unit 21 controls the components including the liquid dropping device 8 and the stage base 9.

When imprint is performed on the wafer Wx, the wafer Wx placed on the sample stage 5 is moved to a location right under the liquid dropping device 8. Then, the resist is dropped at a predetermined shot position of the wafer Wx. At this time, the control unit 21 causes the liquid dropping device 8 to drop the resist under various resist dropping conditions (in terms of drop position, drop amount, and the like) that are set shot by shot.

Thereafter, the wafer Wx on the sample stage 5 is moved to a location right under the template T. Then, the template T is pressed against the resist on the wafer Wx. At this time, the control unit 21 brings the template T and the resist into contact with the stage base 9 only for various lengths of contact time that are set shot by shot.

After the template T has been brought into contact with the resist for a predetermined length of time, the UV light source 10 is caused to irradiate the resist in this state to harden the resist is hardened, such that the resist on the wafer Wx is patterned into transfer patterns corresponding to the template patterns.

The imprint process on the next shot is carried out thereafter. Then, at the completion of the imprint process on all shots on the wafer Wx, resist patterns on the wafer Wx are observed by use of the optical microscope 11. Then, on the basis of whether there is an unfilled defect for the shots, it is determined which shot (a combination of a resist dropping condition and contact time) comes up to the standard.

In the embodiment, resist patterns are formed on the wafer Wx under various process conditions, and the most suitable process condition is determined on the basis of unfilled defects in the resist patterns. A process condition here is determined by, for example, a kind of the resist, a position onto which a droplet of the resist is dropped (drop position condition), the amount of the resist to be dropped (drop amount condition), a time for filling the resist (filling time condition). The drop position condition here is a position onto which a resist droplet is ejected on the wafer Wx, and the drop amount condition is the ejected amount of a resist droplet, and the filling time condition is a contact time for which the template T is in contact with the resist.

For example, the first to n-th wafers Wx (where n is a natural number) are prepared, and resist patterns are formed on the wafers Wx by use of first to n-th kinds of resist, respectively, under various resist dropping conditions and for various contact times. Then, a kind of resist that is the most suitable for the process is determined on the basis of which kind of resist has the smallest number of shots that are with unfilled defects occurred in forming the resist patterns. Additionally, allowable dropping conditions and allowable contact times, for example, are determined on the basis of in which shots unfilled defects occur in a case where resist patterns are formed by use of the thus determined kind of resist. In this manner, an appropriate process for imprint lithography is determined with defects (unfilled defects) used as an index, the defects being peculiar to imprint lithography such as NIL.

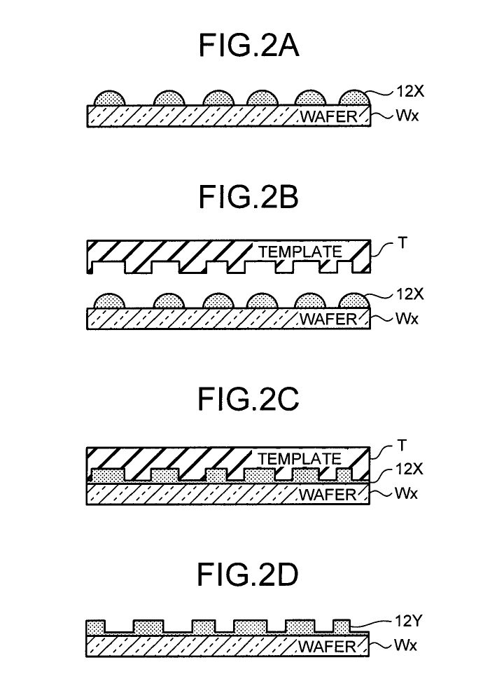

Here, a procedure in which imprint steps are performed will be explained. FIGS. 2A to 2D are explanatory diagrams for a procedure in which imprint steps are performed. FIGS. 2A to 2D are cross-sectional views of the wafer Wx, the template T, and the like during the imprint steps.

As illustrated in FIG. 2A, droplets of resist 12X are dropped on the top surface of the wafer Wx. Droplets of the resist 12X dropped on the wafer Wx spreads over the surface of the wafer Wx. Then, as illustrated in FIG. 2B, the template T is moved toward the resist 12X and, as illustrated in FIG. 2C, is pressed against the resist 12X. Thus, the resist 12X flows within of the template patterns of the template Tx by capillary phenomenon when the template T, which has been formed by engraving, for example, a quartz substrate, is brought into contact with the resist 12X.

After the resist 12X is filled into the template T for a preset length of time, UV light is applied thereto. The resist 12X thereby hardens. Then, as depicted in FIG. 2D, resist patterns that are inverse to the template patterns are formed on the wafer Wx by performing mold release of the template T from hardened resist 12Y.

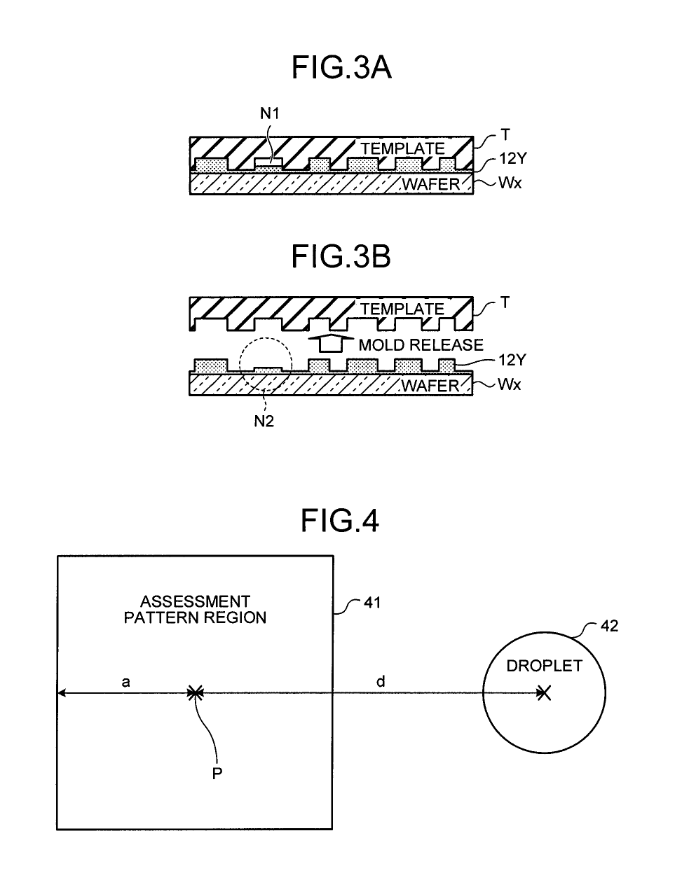

Then, unfilled defects which occur in a resist pattern forming step using imprint will be explained. FIGS. 3A and 3B are explanatory diagrams for unfilled defects. FIGS. 3A and 3B are cross-sectional views of the wafer Wx, the template T, and the like in a mold release process in the imprint steps.

After the template Tx is brought into contact with the resist 12X and the resist is filled into the template patterns, the resist 12X is hardened, thereby turning into the resist 12Y. When the resist is filled into the template patterns, a resist-unfilled position N1 occurs as depicted in FIG. 3A unless a process condition is appropriate. In a case where there is the resist-unfilled position N1 like this, the resist unfilled position N1 appears in the form of an unfilled defect N2, as depicted in FIG. 3B, after mold release of the template T from the resist 12Y is performed. In this embodiment, the occurrence frequency of the unfilled defect N2 is adjusted from shot to shot by performing imprint while intentionally changing the drop position condition, the drop amount condition, and the filling time condition.

Next, the resist dropping position (a drop position condition) of resist dropping conditions set shot by shot is described. FIG. 4 is an explanatory diagram for a resist dropping position. Among the respective template patterns formed in the shots, an assessment pattern which is to be subjected to pattern assessment is set beforehand. In addition, a position (assessment pattern positions P) on the wafer Wx to be pressed with the assessment pattern is derived beforehand. Further, a predetermined range centered on this assessment pattern position P is set as an assessment pattern region 41. The assessment pattern region 41 is a rectangular region, the center of which is located at the assessment pattern position P, and the rectangular region longitudinally and laterally has a predetermined distance of a from this central position. In other words, the assessment pattern region 41 is a rectangular region, at the center of which the assessment pattern position P is located, and the rectangular region has a longitudinal distance of 2 a and a lateral distance of 2 a.

As a position onto which the resist 12X is dropped, a position onto which a droplet 42 is dropped is set. The position of the droplet 42 is, for example, a position distant by a predetermined distance of d from the assessment pattern position P. In this embodiment, the distance of d from the assessment pattern position P is variously changed from shot to shot on the wafer Wx. This allows for assessment of a relation between the position (distance) at which the droplet 42 is from the assessment pattern position P, and whether there is the unfilled defect N2. In other words, determination is possible as to how much distance is suitable from the assessment pattern position P to the position onto which the droplet 42 is dropped so as to effect formation of a resist pattern without causing the unfilled defect N2.

After having set the position onto which the droplet 42 of the resist is dropped shot by shot, resist patterns are formed on the wafer Wx under this dropping condition. In this embodiment, various process conditions are combined, and a resist patterns is formed on each of the wafers Wx according to the process condition.

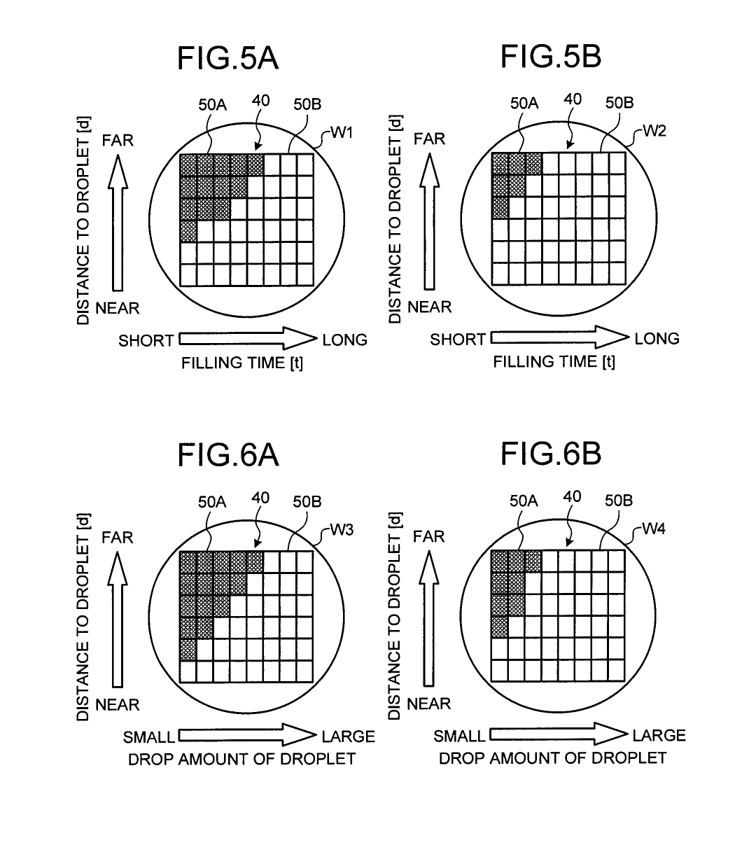

Here, an assessment method with respect to the unfilled defect N2 in a case where a time for filling the resist 12X (a filling time condition), and a position onto which the droplet 42, which is a resist droplet, is dropped (a drop position condition) are changed from shot to shot will be explained. FIGS. 5A and 5B are exemplary diagrams of an assessment result with respect to unfilled defects in a case where the filling time condition and the drop position condition are changed from shot to shot. In the assessment results (defect test results) of FIGS. 5A and 5B, shots having an occurrence frequency of unfilled resist defects that exceeds a standard are indicated as defective shots 50A, whereas the other shots are indicated as non-defective shots 50B.

For example, the imprint apparatus 101 is adapted to perform imprint on a wafer W1 serving as the wafer Wx by using first resist R1 (not illustrated), and to perform imprint on a wafer W2 serving as the wafers Wx by using second resist R2 (not illustrated). The first resist R1 is resist having a composition different from that of the second the resist R2.

The imprint apparatus 101 sets beforehand, for the wafers W1 and W2, the same shot map 40 constituted by plural shots. Additionally, the imprint apparatus 101 sets beforehand imprint conditions (here, determined by the filling time condition and the drop position condition) for the wafers W1 and W2, the imprint conditions being obtained by variously changing, from shot to shot, a time for filling the resist 12X and a position onto which the droplet 42 is dropped. Additionally, the imprint apparatus 101 sets beforehand the same imprint condition for a shot position on the wafer W1 and a shot position on the wafer W2 that correspond to each other.

Specifically, the plural drop position conditions are prepared beforehand as conditions (drop recipe) where positions from which the resist is dropped are set for the wafers W1 and W2. For example, the assessment pattern region 41 of 50-μm square is set as the assessment pattern region 41 depicted in FIG. 4. Further, for example, the eight drop position conditions are prepared beforehand in which the distances d from the assessment pattern position P to the center of the droplet 42 are set to 0, 50, 100, 150, 200, 250, 300, and 350 μm.

Additionally, the plural filling time conditions are prepared beforehand as conditions (filling recipe) where times taken for filling the resist 12X are set for the wafers W1 and W2. For example, the eight filling time conditions are prepared in which times, for which the resist 12X is filled, are set to 5, 10, 15, 20, 25, 30, 35, and 40 seconds. Then, any one of combinations each including any one of the eight drop position conditions and any one of the eight filling time conditions is set for shot by shot. In this manner, the single wafer Wx is subjected to imprint under 64 conditions obtained as the combinations of the eight drop position conditions and the eight filling time conditions.

After the imprint conditions are set, the imprint apparatus 101 brings in the wafer W1, and performs imprint on the wafer W1. Specifically, the control unit 21 controls the liquid dropping device 8 such that, with respect to a first shot on the wafer W1, the liquid dropping device 8 drops the droplet 42 under a first drop position condition.

Further, the control unit 21 controls movement of the stage base 9 such that, with respect to the first shot on the wafer W1, the resist 12X is filled into the template patterns under a first filling time condition.

Thereafter, the control unit 21 controls the liquid dropping device 8 such that, with respect to an m-th shot (m is a natural number of 2 or more) on the wafer W1, the liquid dropping device 8 drops the droplet 42 under an m-th drop position condition. Further, the control unit 21 controls movement of the stage base 9 such that, with respect to the m-th shot on the wafer W1, the resist 12X is filled into the insides of the template patterns under a m-th filling time condition. The control unit 21 repeats the dropping of the droplet 42 and the filling of the resist 12X into the template patterns, and a mold release process from shot to shot on the wafer W1.

The control unit 21 thereby has imprint performed on the shot positions on the wafer W1 under conditions obtained by variously combining the drop position conditions and the filling time conditions. Likewise, the control unit 21 has imprint performed on the shot positions on the wafer W2 under conditions obtained by variously combining the drop position conditions and the filling time conditions.

FIGS. 5A and 5B depict assessment results about the unfilled defects N2, the assessment results each being obtained in a case where, while a distance from the assessment pattern position P to the droplet 42 is changed from row to row of the shot map 40, a time for filling the resist 12X is changed from column to column of the shot map 40.

After imprint has been completely performed on the shots on the wafer W1, observation are made about unfilled defects N2 on the wafer W1 by use of the optical microscope 11. Likewise, after imprint has been completely performed on the shots on the wafer W2, observations are made about unfilled defects N2 on the wafer W2 by use of the optical microscope 11. The presence or absence of the unfilled defect N2 is determined, for example, on the basis of whether any unfilled defect N2 exists in the assessment pattern region 41.

FIG. 5A depicts distribution of the defective shots 50A and the non-defective shots 50B in a case where imprint has been performed on the wafer W1 by use of the first resist R1. Among the shots on the wafer W1, the defective shots 50A are those for which the resist 12X has been filled for short periods of time, and those for which distances from the assessment pattern positions P and the corresponding droplets 42 are long. The wafer W1 here has 13 shots found as the defective shots 50A.

FIG. 5B depicts distribution of the defective shots 50A and the non-defective shots 50B in a case where imprint has been performed on the wafer W2 by use of the second resist R2. Among the shots on the wafer W2, the defective shots 50A are those for which the resist has been filled for short periods of time, and those for which distances from the assessment pattern positions and the corresponding droplets are long. The wafer W2 here has 6 shots found as the defective shots 50A.

As a result, the second resist R2 has wider margins for the filling times and for the distances to the droplets 42 in terms of occurrence of defects, and can be determined to be a resist better than the first resist R1. Additionally, in the case of using the second resist R2, it can be determined as being appropriate to perform imprint with the “filling time” and the “distance to the droplet” that result in any one of the non-defective shots 50B depicted in FIG. 5B.

For example, in a case where the maximum allowable distance as the distance d from the assessment pattern position P to the center of the droplet 42 is 100 μm, an allowable distance between the droplets 42 that are adjacent to each other is set to, for example, 100×2 =200 μm.

Next, an assessment method with respect to the unfilled defects N2 in a case where the drop amount of the resist 12X (a drop amount condition) and the drop position of the droplet 42 (a drop position condition) are changed from shot to shot will be explained. FIGS. 6A and 6B are explanatory diagrams of an assessment result in terms of unfilled defects when the drop amount condition and the dropping position condition are changed from shot to shot.

For example, the imprint apparatus 101 performs imprint on a wafer W3 serving as the wafer Wx by using the first resist R1, and performs imprint on a wafer W4 serving as the wafer Wx by using the second resist R2.

The imprint apparatus 101 sets beforehand, for the wafers W3 and W4, the same shot map 40 constituted by plural shots. Additionally, the imprint apparatus 101 sets beforehand imprint conditions (here, determined by the drop amount condition and the drop position condition) for the wafers W3 and W4, the imprint conditions being obtained by variously changing, from shot to shot, the drop amount of the resist 12X, and a position onto which the droplet 42 is dropped. Additionally, the imprint apparatus 101 sets beforehand the same imprint condition for a shot position on the wafer W3 and a shot position on the wafer W4 that correspond to each other.

Specifically, the plural drop amount conditions are prepared beforehand as conditions (drop recipe) where amounts by which the resist is dropped are set for the wafers W3 and W4. Additionally, the plural drop position conditions are prepared beforehand as conditions where positions from which the resist is dropped are set for the wafers W3 and W4.

After the imprint conditions are set, the imprint apparatus 101 repeats the dropping of the droplet 42, the filling of the resist 12X into the template patterns, and a mold release process, as in the case of the wafers W1 and W2, with respect to the shots on the wafers W3 and W4 under corresponding ones of the various imprint conditions.

FIGS. 6A and 6B depict assessment results about the unfilled defects N2, the assessment results being obtained in a case where, while a distance from the assessment pattern position P to the droplet 42 is changed from row to row of the shot map 40, the drop amount of the droplet 42 is changed from column to column of the shot map 40.

FIG. 6A depicts distribution of the defective shots 50A and the non-defective shots 50B in a case where imprint has been performed on the wafer W3 by use of the first resist R1. Among the shots on the wafer W3, the defective shots 50A are those for which the drop amounts of the droplets 42 are small, and those for which distances from the assessment pattern positions P and the corresponding droplets 42 are long. The wafer W3 here has 15 shots found as the defective shots 50A.

FIG. 6B depicts distribution of the defective shots 50A and the non-defective shots 50B in a case where imprint has been performed on the wafer W4 by use of the second resist R2. Among the shots on the wafer W4, the defective shots 50A are those for which the drop amounts of the droplets 42 are small, and those for which distances from the assessment pattern positions P and the corresponding droplets 42 are long. The wafer W4 here has 8 shots found as the defective shots 50A.

As a result, the second resist R2 has wider margins for the drop amounts of the droplets 42 and for the distances to the droplets 42 in terms of occurrence of defects, and can be determined to be a resist better than the first resist R1. Additionally, in the case of using the second resist R2, it can be determined as being appropriate to perform imprint with the “drop amount of the droplet” and the “distance to the droplet” that result in any one of the non-defective shot 50B depicted in FIG. 6B.

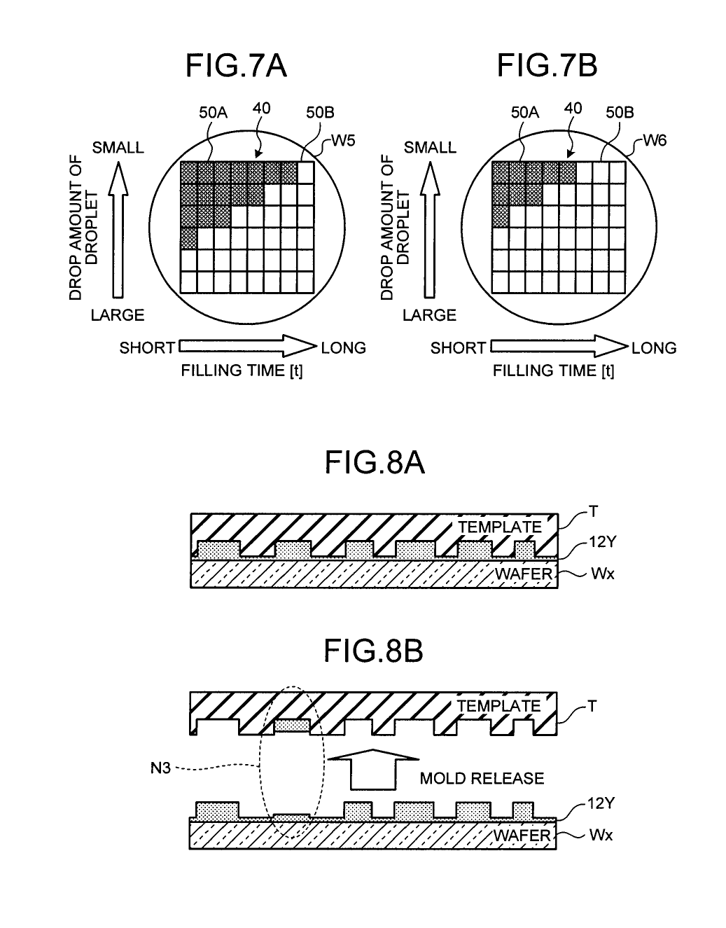

Next, an assessment method with respect to the unfilled defects N2 in a case where a time for filling the resist 12X (a filling time condition), and the drop amount of the resist 12X (a drop amount condition) are changed from shot to shot will be explained. FIGS. 7A and 7B are exemplary diagrams of an assessment result in terms of unfilled defects when the filling time condition and the drop amount condition are changed from shot to shot.

For example, the imprint apparatus 101 is adapted to perform imprint on a wafer W5 serving as the wafer Wx by using the first resist R1, and to perform imprint on a wafer W6 serving as the wafer Wx by using the second resist R2.

The imprint apparatus 101 sets beforehand, for the wafers W5 and W6, the same shot map 40 constituted by plural shots. Additionally, the imprint apparatus 101 sets beforehand imprint conditions (here, determined by the drop amount condition and the filling time condition) for the wafers W5 and W6, the imprint conditions being obtained by variously changing, from shot to shot, the drop amount of the resist 12X, and a time taken for filling the resist 12X. Additionally, the imprint apparatus 101 sets beforehand the same imprint condition for a shot position on the wafer W5 and a shot position on the wafer W6 that correspond to each other.

Specifically, the plural drop amount conditions are prepared beforehand as conditions where the drop amounts of the droplets 42 are set for the wafers W5 and W6. Additionally, the plural filling time conditions are prepared beforehand as conditions where times taken for filling the resist 12X are set for the wafers W5 and W6.

After the imprint conditions are set, as in the case of the wafers W1 and W2, the imprint apparatus 101 repeats the dropping of the droplet 42, the filling of the resist 12X into the template patterns, and a mold release process with respect to the shots on the wafers W3 and W4 under corresponding ones of the various imprint conditions.

FIGS. 7A and 7B depict assessment results about the unfilled defects N2, the assessment results being obtained in a case where, while the drop amount of the droplet 42 is changed from row to row of the shot map 40, a time for filling the resist 12X is changed from column to column of the shot map 40.

FIG. 7A depicts distribution of the defective shots 50A and the non-defective shots 50B in a case where imprint has been performed on the wafer W5 by use of the first resist R1. Among the shots on the wafer W5, the defective shots 50A are those for which the drop amounts of the droplets 42 are small, and those for which times taken for filling the resist 12X are short. The wafer W5 here has 16 shots found as the defective shots 50A.

FIG. 7B depicts distribution of the defective shots 50A and the non-defective shots 50B in a case where imprint has been performed on the wafer W6 by use of the second resist R2. Among the shots on the wafer W6, the defective shots 50A are those for which the drop amounts of the droplets 42 are small, and those for which times taken for filling the resist 12X are short. The wafer W6 here has 9 shots found as the defective shots 50A.

As a result, the second resist R2 has wider margins for the drop amounts of the droplets 42 and for the filling times in terms of occurrence of defects, and can be determined to be a resist better than the first resist R1. Additionally, in the case of using the second resist R2, it can be determined as being appropriate to perform imprint with the “drop amount of the droplet” and the “filling time” that result in any one of the non-defective shots 50B depicted in FIG. 7B.

Thus, the use of the assessment methods of this embodiment allows for distinction at the first glance how good or bad the resist is. For example, the unfilled defects N2 are caused by the following factors (1) to (5):

(1) A recess pattern of the template T is so large that the capillary phenomenon hardly works;

(2) The drop amount of the resist 12X is insufficient relative to the size of the recess pattern;

(3) The distance between the drop position of the droplet 42 to the assessment pattern position P is long;

(4) The filling time is so insufficient that air bubbles inside the recess pattern are not eliminated; and

(5) The wettability of the resist 12X against the wall surface of the recess pattern is low.

In this embodiment, imprint is performed on one wafer Wx under various process conditions (determined by the drop position condition, the drop amount condition, and the filling time condition), such that an appropriate process condition is selectable in relation to the above-described defect-causing factors (1) to (5).

For example, imprint is performed under various drop position conditions, such that an appropriate drop position condition is selectable in relation to the defect-causing factor (2). Additionally, imprint is performed under various drop amount conditions, such that an appropriate drop amount condition is selectable in relation to the defect-causing factor (3). Additionally, imprint is performed under various filling time conditions, such that an appropriate filling time condition is selectable in relation to the defect-causing factor (4).

Additionally, imprint is performed by use of plural kinds of the resist 12X, such that an appropriate kind of the resist 12X is selectable in relation to the defect-causing factors (1) to (5). For example, imprint is performed with various kinds of the resist 12X, such that an appropriate one of the resist 12X is selectable in relation to the defect-causing factors (1) and (5).

An assessment (selection) of the resist 12X and a determination on which one of the process conditions (determined by the drop position condition, the drop amount condition, the filling time condition) is used in imprint are made per layer in a wafer process. When semiconductor devices (semiconductor integrated circuits) are produced, a film-forming process on the wafer Wx, an imprint process using the template T, and an etching process to be performed from the top of resist patterns formed by the imprint process are repeated from layer to layer. In that case, in the imprint process, imprint is performed by use of the kind of the resist 12X selected in this embodiment and under the process condition selected in this embodiment.

Note that the imprint apparatus 101 may set three or more kinds of process conditions for one wafer Wx. For example, the imprint apparatus 101 may set a combination of three conditions including a drop position condition, a drop amount condition, and a filling time condition for the shots on one wafer Wx.

Additionally, the imprint apparatus 101 may set one kind of process condition for one wafer Wx. In other words, a process condition for imprint may be assessed by variously setting at least one of the drop position condition, the drop amount condition, and the filling time condition for the shots.

Thus, according to the first embodiment, the imprint apparatus 101 is adapted to perform imprint on the wafer Wx under various process conditions (determined by the drop position condition, the drop amount condition, and the filling time condition) from shot to shot and by use of various kinds of resist 12X, such that efficient process assessment in imprint is achieved.

### Second Embodiment

Next, a second embodiment of this invention will be explained with reference to FIGS. 8A to 10B. In the second embodiment, template patterns are transferred under various process conditions (mold release conditions) from shot to shot on the wafer Wx so that assessment in terms of mold release defects, in which a resist pattern (a hardened photo-curing agent) is peeled off from the wafer Wx at the time of mold release, can be made. In this embodiment, assessment is made as to a kind of resist that enables prevention of mold release defects and a process margin in imprint where mold release defects are preventable.

The control unit 21 included in the imprint apparatus 101 of this embodiment is adapted to control a mold release speed and a mold release angle when mold release of the template T from the hardened resist 12Y is carried out. Specifically, the control unit 21 is adapted to control a mold release speed and a mold release angle by controlling the moving speed and the moving direction of the stage base 9 at the time of mold release.

Then, mold release defects, which occur in a resist pattern forming process through imprint, will be explained. FIGS. 8A and 8B are explanatory diagrams for mold release defects. FIGS. 8A and 8B depict cross-sectional views of the wafer Wx, the template T, and the like in a mold release process of the imprint steps.

After the template Tx is brought into contact with the resist 12X and the resist is filled into the template patterns, the resist 12X is hardened to turn into the resist 12Y (FIG. 8A). Thereafter, mold release of the template T from the resist 12Y is carried out. If a mold release speed and a mold release angle at the time of mold release are not appropriate, a mold release defect N3 occurs as depicted in FIG. 8B. The mold release defect N3 is a defect where a resist pattern is chipped off with a portion of the resist 12Y having attached to the inside of the template patterns as a residual substance of resin.

In this embodiment, imprint is performed on the wafer Wx under various mold release conditions (in terms of mold release speed and mold release angle) so that a relationship between a mold release speed and the mold release defect N3, a relationship between a mold release angle and the mold release defect N3, and a relationship among a mold release speed, a mold release angle, and the mold release defect N3 are assessed. Thus, in this embodiment, the occurrence frequency of the mold release defect N3 is adjusted from shot to shot by performing imprint while intentionally changing a mold release speed and a mold release angle for the template T.

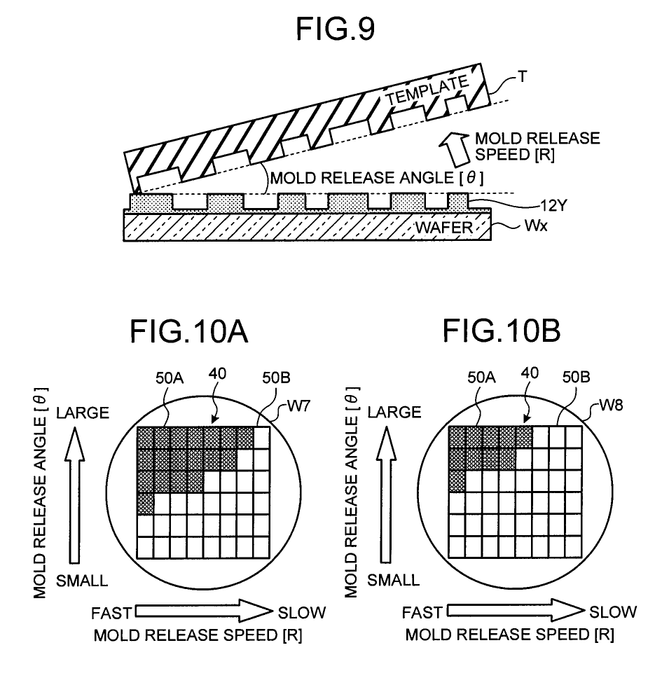

FIG. 9 is an explanatory diagram for a mold release speed and a mold release angle. FIG. 9 depicts a cross-sectional view of the wafer Wx, the template T, and the like in the mold release process in the imprint steps. After the template T is brought into contact with the resist 12X and the resist is filled into the template patterns, the resist 12X is hardened to turn into the resist 12Y (FIG. 8A).

Thereafter, mold release of the template T from the resist 12Y is carried out. The angle between the principle surface (the patterned surface) of the template T and the principal surface (the surface patterned into the resist patterns) of the resist 12Y at this time is a mold release angle (0). Additionally, the speed of the template T when the template T is separated from the resist 12Y in a fixed condition is a mold release speed (R). The speed of the template T is a speed at which a portion (extreme end) of the template T that separates from the resist 12Y at the start moves from the resist 12Y.

In this embodiment, the mold release speed and the mold release angle are changed variously from shot to shot on the wafer Wx. Thus, in this embodiment, the resist patterns are formed on the wafers Wx with combinations of the various mold release speeds and the various mold release angles.

Next, an assessment method with respect to the mold release defect N3 in a case where the mold release speed and the mold release angle are changed from shot to shot will be explained. FIGS. 10A and 10B are exemplary diagrams of an assessment result with respect to the mold release defect in a case where the mold release speed and the mold release angle are changed from shot to shot. FIGS. 10A and 10B depict examples of the assessment result with respect to the mold release defect N3 as the respective defectiveness assessment results of the shots in the same manner as FIGS. 5A to 7B.

For example, the imprint apparatus 101 is adapted to perform imprint on a wafer W7 serving as the wafer Wx by using the first resist R1, and to perform imprint on a wafer W8 serving as the wafer Wx by using the second resist R2.

The imprint apparatus 101 sets beforehand the same shot map 40 constituted by plural shots for the wafers W7 and W8. Additionally, the imprint apparatus 101 sets imprint conditions (here, determined by a mold release speed condition and a mold release angle condition) obtained by variously changing the mold release speed and the mold release angle for the wafers W7 and W8 from shot to shot. Additionally, the imprint apparatus 101 sets beforehand the same imprint condition for a shot position on the wafer W7 and a shot position on the wafer W8 that correspond to each other.

Specifically, plural conditions where mold release speeds are set are prepared beforehand for the wafers W7 and W8. Additionally, plural conditions where mold release angles are set are prepared beforehand for the wafers W7 and W8. For example, plural speeds are selected from those between 10 mm/s and 100 mm/s and set beforehand as the mold release speeds, whereas plural angles are selected from those of 0 degrees to 10 degrees and set as the mold release angles.

After the imprint conditions are set, the imprint apparatus 101 repeats dropping of the droplet 42, filling of the resist 12X into the template patterns, and a mold release process on the wafers W7 and W8 as in the case of the wafers W1 and W2. Then, in the mold release process, the template T is separated from the resist 12Y under the various mold release conditions from shot to shot.

FIGS. 10A and 10B depict assessment results with respect to the mold release defect N3 in a case where imprint is performed with the mold release angle changed row by row of the shot map 40, and with the mold release speed changed column by column of the shot map 40.

FIG. 10A depicts distribution of the defective shots 50A and the non-defective shots 50B in a case where imprint has been performed on the wafer W7 by use of the first resist R1. Among the shots on the wafer W7, the defective shots 50A are those for which the mold release speeds are fast, and those for which the mold release angles are large. The wafer W7 here has 18 shots found as the defective shots 50A.

FIG. 10B depicts distribution of the defective shots 50A and the non-defective shots 50B in a case where imprint has been performed on the wafer W8 by use of the second resist R2. Among the shots on the wafer W8, the defective shots 50A are those for which the mold release speeds are fast, and those for which the mold release angles are large. The wafer W8 here has 10 shots found as the defective shots 50A.

As a result, the second resist R2 has wider margins (room) for occurrence of defects depending on the mold release speed and on the mold release angle, and can be determined to be a resist better than the first resist R1. Additionally, in the case of using the second resist R2, it can be determined as being appropriate to perform imprint with the “mold release speed” and the “mold release angle” that result in any one of the non-defective shots 50B depicted in FIG. 10B.

In this embodiment, process conditions for imprint are assessed by causing the imprint apparatus 101 to set at least any one of the mold release speed and the mold release angle.

Thus, according to the second embodiment, the imprint apparatus 101 performs imprint on the shots of the wafers Wx under corresponding ones of various process conditions (determined by the mold release speed and the mold release angle) and by use of various kinds of the resist 12X. Thus, efficient process assessment in imprint is achieved.

The first and second embodiments thus allows for efficient performance of process assessment in imprint.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint apparatus comprising:
a resist dropping unit adapted to drop resist serving as a transfer material onto a substrate onto which template patterns formed on a template are to be transferred;
a patterning unit adapted to pattern the resist into transfer patterns by, in addition to pressing the template for a predetermined length of time against the resist on the substrate to fill the resist into the template patterns, hardening the resist after the filling and thereafter performing a mold release process to separate the template from the hardened resist, the transfer patterns corresponding to the template patterns; and
a control unit configured to control a condition of dropping in a resist dropping process to be performed by the resist dropping unit, in such a manner that the condition of dropping is changed shot by shot for a plurality of shots set on the substrate, wherein
the control unit controls, as the condition of dropping, the distance to the position of a droplet of the resist to be dropped onto the substrate from a position on the substrate to be pressed with an assessment pattern, the assessment pattern being one of the template patterns that is to be assessed.

2. The imprint apparatus according to claim 1, wherein the control unit further controls the amount of a droplet of the resist to be dropped onto the substrate.

3. The imprint apparatus according to claim 1, wherein the control unit controls a condition of filling in a process of the filling to be performed by the patterning unit, in such a manner that the condition of filling is changed shot by shot for the plurality of shots set on the substrate.

4. The imprint apparatus according to claim 3, wherein the control unit controls, as the condition of filling, a time for filling when the resist is filled into the template patterns.

5. The imprint apparatus according to claim 1, wherein the control unit controls a condition of mold release in the mold release process to be performed by the patterning unit, in such a manner that the condition of mold release is changed shot by shot for the plurality of shots set on the substrate.

6. The imprint apparatus according to claim 5, wherein the control unit controls, as the condition of mold release, at least any one of a mold release speed and a mold release angle.

7. An imprint method comprising:
dropping resist serving as a transfer material onto a substrate onto which template patterns formed on a template are to be transferred; and
patterning the resist into transfer patterns by, in addition to pressing the template for a predetermined length of time against the resist on the substrate to fill the resist into the template patterns, hardening the resist after the filling and thereafter performing a mold release process to separate the template from the hardened resist, the transfer patterns corresponding to the template patterns, wherein
in patterning the resist into the transfer patterns, a condition of dropping at the time of dropping the resist is controlled in such a manner that the condition of dropping is changed shot by shot for a plurality of shots set on the substrate, and in the controlling, the distance to the position of a droplet of the resist to be dropped onto the substrate from a position on the substrate to be pressed with an assessment pattern is controlled as the condition of dropping, the assessment pattern being one of the template patterns that is to be assessed.

8. The imprint method according to claim 7, wherein, in the controlling, the amount of a droplet of the resist to be dropped onto the substrate is further controlled as the condition of dropping.

9. The imprint method according to claim 7, wherein, in the controlling, a condition of filling in a process of the filling is controlled in such a manner that the condition of filling is changed shot by shot for the plurality of shots set on the substrate.

10. The imprint method according to claim 9, wherein, in the controlling, a time for filling when the resist is filled into the template patterns is controlled as the condition of filling.

11. The imprint method according to claim 7, wherein, in the controlling, a condition of mold release in the mold release process is controlled in such a manner that the condition of mold release is changed shot by shot for the plurality of shots set on the substrate.

12. The imprint method according to claim 11, wherein, in the controlling, at least any one of a mold release speed and a mold release angle is controlled as the condition of mold release.

13. A process condition selection method comprising:
dropping resist serving as a transfer material onto a substrate onto which template patterns formed on a template are to be transferred;
patterning the resist into transfer patterns by, in addition to pressing the template for a predetermined length of time against the resist on the substrate to fill the resist into the template patterns, hardening the resist after the filling and thereafter performing a mold release process to separate the template from the hardened resist, the transfer patterns corresponding to the template patterns; and
on the basis of shapes of resist patterns into which the resist has been patterned, selecting a process condition to be used for imprint, wherein
in patterning the resist into the transfer patterns, a condition of dropping at the time of dropping the resist is controlled in such a manner that the condition of dropping is changed shot by shot for a plurality of shots set on the substrate, and in the controlling, the distance to the position of a droplet of the resist to be dropped onto the substrate from a position on the substrate to be pressed with an assessment pattern is controlled as the condition of dropping, the assessment pattern being one of the template patterns that is to be assessed.

14. The process condition selection method according to claim 13, wherein patterning onto the resist is performed with different kinds of the resist for different substrates, and a kind of the resist is selected as the process condition to be used in the imprint.

15. The process condition selection method according to claim 13, wherein, in the controlling, the amount of a droplet of the resist to be dropped onto the substrate is further controlled as the condition of dropping.

16. The process condition selection method according to claim 13, wherein, in the controlling, a condition of filling in a process of the filling is controlled in such a manner that the condition of filling is changed shot by shot for the plurality of shots set on the substrate.

17. The process condition selection method according to claim 16, wherein, in the controlling, a time for filling when the resist is filled into the template patterns is controlled as the condition of filling.

18. The process condition selection method according to claim 13, wherein, in the controlling, a condition of mold release in the mold release process is controlled in such a manner that the condition of mold release is changed shot by shot for the plurality of shots set on the substrate.

19. The process condition selection method according to claim 18, wherein, in the controlling, at least any one of a mold release speed and a mold release angle is controlled as the condition of mold release.

20. A semiconductor device, which is a product manufactured according to any one condition of dropping of the conditions of dropping selected based on the transfer patterns obtained by use of the imprint method of claim 7.
